(19) United States
(12) Patent Application Publication
(10) Pub. No.: US 2024/0203932 A1
(43) Pub. Date: Jun. 20, 2024

(54) POWER MODULE WITH IMPROVED ELECTRICAL COMPONENTS

(71) Applicant: Danfoss Silicon Power GmbH, Flensburg (DE)

(72) Inventors: Tobias SCHUETZ, Flensburg (DE); Robert ROESNER, Oberscheissheim (DE); Guido MANNMEUSEL, Kosel (DE); Henning STRÖBEL-MAIER, Wanderup (DE); Xiaoting DONG, Ismaning (DE); Lukas TATZIG, Flensburg (DE)

(21) Appl. No.: 18/555,751

(22) PCT Filed: Apr. 22, 2022
(86) PCT No.: PCT/EP2022/060772

§ 371 Date: Oct. 17, 2023

(30) Foreign Application Priority Data
Apr. 25, 2021 (DK) PA202100408

(51) Int. Cl. H01L 23/00; H01L 25/07

(52) U.S. Cl. CPC H01L 24/49; H01L 24/45; H01L 24/48; H01L 25/072; H01L 2224/45014; H01L 2224/48137; H01L 2224/4917; H01L 2224/49175; H01L 2924/10272

(57) ABSTRACT

A power semiconductor module (1) having two or more semiconductor components (3, 53, 55) which are electrically connected in parallel. The first power contacts (7) of each semiconductor component (3, 53, 55) are electrically connected to a first track (9). The second power contacts (11) of each semiconductor component (3, 53, 55) are electrically connected to a second track (13) by connecting means (15). The connecting means (15) include at least a first connecting element (17) connecting a first semiconductor component (53) of the two or more semiconductor components (3) to the second track (13) via a first contact area (19), and a second connecting element (21) connecting a second semiconductor component (55) of the two or more semiconductor components (3) with the second track (13) by a second contact area (23). The second connecting element (21) partially overlaps the first contact area (19) and/or first connecting element (17).

### CROSS-REFERENCE TO RELATED APPLICATIONS

This application is a National Stage application of International Patent Application No. PCT/EP2022/060772, filed on Apr. 22, 2022, which claims priority to Danish Patent Application No. PA202100408, filed on Apr. 25, 2021, each of which is hereby incorporated by reference in its entirety.

### TECHNICAL FIELD

Semiconductor power modules are widely used in industry. For example, such a power module may be used for the controlled switching of high currents and can be used in power converters (such as inverters) to convert DC to AC or vice versa, or for converting between different DC or AC voltages or frequencies of AC. Such inverters are used in interfaces between two or more electrical components working in different voltage of frequency areas. Particularly, power modules are being increasingly utilised in vehicles, such as electrical or hybrid vehicles, where the conversion and/or control of electrical power is important. In such applications, there are very great constraints on size, weight and efficiency.

### BACKGROUND

A semiconductor power module is designed to fulfil four major characteristics: High power conversion efficiency, high power density, low cost and high reliability. Factors such as lifetime and quality are also taken into account. In order to achieve a high power density, high performance wide-bandgap semiconductors, such as Silicon Carbide (SiC) semiconductor switches may be used, since they generally outperform standard silicon-based semiconductor switches, e.g. Insulated Gate Bipolar Transistors (IGBT). SiC devices put high demands on the design of the power module from thermal and electrical standpoint. The wide-bandgap semiconductors (e.g., SiC or GaN semiconductor switches) have the characteristic that they can switch very fast, meaning that the transition from conduction to blocking mode and vice versa takes only a few nanoseconds.

SiC MOSFETs are used as the semiconductor switches in applications where highest efficiency in a small volume is required by the application. SiC MOSFETs show fast switching speeds and low on-state resistance at the same time. In particular wide band gap semiconductors outperform silicon based semiconductors in their partial load efficiency which increases the range of vehicles using an energy storage with limited capacity. Since SiC wafers are expensive to manufacture, and with current manufacturing processes it is hard to fabricate components with an acceptably low crystal failure amount, the die are typically very small (for example, 5-25 mm2). This keeps yield losses low, but restricts the total current capacity of an individual SiC semiconductor switch. In order to achieve high output powers, several of these small semiconductor switches (for example MOSFETs) need to be operated in parallel. In applications such as automotive power conversion, the use of multiple semiconductor switches in parallel takes up space within the semiconductor power module, yielding potentially larger modules. However, space is at a premium within a vehicle, and increasing the size of modules is not generally an option. It is therefore a great advantage if innovative design of layouts can both accommodate multiple semiconductor switches in parallel, a balanced (symmetric) operation, low stray inductance and small overall layout size.

Instead of paralleling multiple semiconductor switches within individual semiconductor power modules, power modules with single chips inside could be paralleled. However, this would require more space in total, and require more complex control components, since each module would need to be controlled separately.

It is known that when a power module contains more than one switch which is connected in parallel, it is often difficult to ensure that the switches switch simultaneously and/or pass equal currents during all switching events. This is e.g. because of different commutation loops, inhomogeneous couplings between power and control circuits and control and power loop inductance differences, which in real-world layouts often disturb the switching behaviour by negatively influencing the symmetry of current distribution among semiconductors in parallel. It is important to design power modules in a way that ensures symmetric behaviour of all paralleled components to avoid the overloading of single components.

In standard modules often dies of the different switching function are placed in a row. That makes it difficult to create equal current paths. This is illustrated in FIG. 1A and FIG. 1B in which is shown a prior art layout wherein a set of semiconductor switches 401-404, are mounted on a positive load track 41 and are electrically connected to a negative load track 42 via a set of wire bonds 43.

An example of such an embodiment of might be a set of SiC MOSFETs 401-404 mounted on the DC positive track 41 via their drain contacts and with the source and gate contacts facing away from the DC positive track 41. The source contacts are connected via wire bonds 43 to the DC negative track 42.

In FIG. 1B, arrows denote the paths of currents of the semiconductor switches 401, 404 placed at the ends of the row of semiconductor switches. It can be clearly seen that the lengths of these arrows, and thus the electrical characteristics of the paths, are significantly different for this particular layout.

The differences in source inductances of semiconductors in parallel have a particularly strong influence on the switching behaviour. This is the case because both the power path (voltage between drain and source and the according current) and the control path (voltage between gate and source and the according current) are influenced by the source inductance. Different source inductances of paralleled semiconductors can lead to different switching times and speeds because of unequal gate-to-source voltages and the different driving strengths or timings which follow from this. Moreover, oscillations between the semiconductor gates caused by different gate-to-source signalling may be introduced. In particular, these oscillations can damage the gate oxide of the semiconductors and thus cause permanent damage to the power module. In addition, the differences in the drain-to-source voltages may cause asymmetric current and loss distribution among semiconductors in parallel. The different length of the source paths can also lead to asymmetric static behaviour of the semiconductors because of asymmetric ohmic resistances in the electrically differing paths.

In prior art layouts such as that seen in FIG. 1A and FIG. 1B, we can see that there are significantly different circuit routing lengths (asymmetries) between the common voltage point, here the negative supply pad marked “−”, and the source connection of each of the semiconductors 401-404.

Such asymmetries mean that a safety margin/derating must be applied to every power module with parallel switches. The safety margin/derating which must be applied strongly depends on the asymmetry of the layout, and leads to a power module being used far below its theoretical current capabilities, and thus at a reduced power output.

The current invention significantly decreases the path length differences, and thereby the electrical difference of the semiconductor individual current loops. Thus, it improves the overall performance of the power module which utilises the invention.

### SUMMARY

The current invention leads to a power module layout which improves the equality of current loops between paralleled semiconductor switches in comparison with prior art power modules.

It is, thus, an object of the present invention to provide a power module where minimum safety margin/derating is required allowing a much more effective and efficient use of the semiconductor components placed inside the power module.

It is a further object of the present invention to provide a semiconductor power module with an improved symmetry of switching behaviour. Such symmetric behaviour allows the current capability of the semiconductor switches to be fully utilised, leading to much more cost-effective applications.

According to a first aspect of the present invention the above objects are fulfilled by providing a power semiconductor module comprising two or more semiconductor components which are electrically connected in parallel. Each of the two or more semiconductor components comprises a first power contact and a second power contact. The first power contacts of each semiconductor component are electrically connected to a first track. The second power contacts of each semiconductor component are electrically connected to a second track by connecting means. The connecting means comprises at least a first connecting element. The first connecting element connects a first semiconductor component of the two or more semiconductor components to the second track via a first contact area. A second connecting element connects a second semiconductor component of the two or more semiconductor components with the second track via a second contact area. The second connecting element partially overlaps the first contact area and/or first connecting element.

Alternatively, the overlap can be full.

By “overlap” it is understood that any element overlapping another element is spaced further away from a surface of the semiconductor power module perpendicular to the principal plane of the semiconductor power module. The two elements are not in electrical contact in an area where the elements are overlapping.

With partial overlap it is understood that the element being overlapped is partially covered by the overlapping element, when seen in plan view from a direction orthogonal to the principal plane of the semiconductor power module. With full overlap it is understood that the element being overlapped is fully covered by the overlapping element.

In this application, the term “semiconductor switching components” is used to include any of a number of known semiconductor switching devices. Examples of such devices are Thyristors, JFETs, IGBTs and MOSFETs, and they may be based on traditional silicon technology or wide-bandgap technologies such as silicon carbide (SiC) or gallium nitride (GaN).

The terms “the first power contacts” and “the second power contacts” refer to the areas on the semiconductor switching components by which the switched currents enter or leave the semiconductor switching components. In a typical IGBT, for example, the first power contact may be the collector contact on the base of the IGBT die, and the second power contact may be the emitter contact found on the upper surface of the die. For a MOSFET “the first power contact” would be drain and “the second power contact” would be source.

The term “track” is here used to specify a circuit track formed from a conductive layer forming part of a substrate and insulated from other tracks by a gap. Some tracks may be suitable for carrying a large current, such as that supplying the electrical load for which the power module is supplying power. Suitability for large currents may be a combination of the width of the track and thickness of the track, forming a large cross-sectional area in addition to good cooling of the track and thus allowing the passage of large currents without undue heating.

The substrate may comprise an insulating base, with conducting tracks to form the circuitry required, attached to the insulating base. A suitable substrate may be a AMB (active metal braze) substrate formed of two conducting copper layers either side of an insulating ceramic layer. Other suitable substrates may include DBA (direct bonded aluminium) or other substrates known in the field.

By “landing area” is meant a theoretical frame which encloses all of the ends of the connecting means where they are attached to the second track. More specifically, the landing area encompasses the contact areas of the connecting elements.

The connecting means may comprise a wire bond, a ribbon bond, an electrically conducting braid such as a woven or knitted braid with multiple strands, or any differently shaped part made of an electrically conductive material.

In the present application “connecting means” refers to the connecting elements connecting the more than two semiconductor components to the second track.

For example in the case of a first and a second semiconductor component “connecting means” refers to the combination of the connecting elements between the second power contacts of the first semiconductor component and the second track and the connecting elements between the second power contacts of the second semiconductor component and the second track.

Due to the second connecting element at least partially overlapping the first contact area and/or the first connecting element, the landing area of the connecting elements can be reduced in size. This reduces the difference in inductance between the individual current loops in the semiconductor power module.

In a further aspect of the invention, the power semiconductor module comprises a third connecting element connecting the first semiconductor component with the second track by a third contact area. The third connecting element partially overlaps the first or second contact area and/or first or second connecting element.

The semiconductor power module can comprise a fourth connecting element connecting the second semiconductor component with the second track via a fourth contact area.

The total number of connecting elements is not limited in general but usually only by the area of the power contacts of the semiconductor component. Thus, larger number of connections and with that a larger number of contact areas can be provided by the invention. This applies for semiconductor components with larger connecting areas and/or when a higher number of semiconductor devices are used in parallel.

The landing area of the connecting elements can be reduced in size, compared to a state of the art module where no overlap of the connecting elements is used.

In a further aspect of the invention, the power semiconductor module comprises at least two connecting elements per semiconductor component. The connecting elements connect the semiconductor component to the second track.

This improves the electrical connection of the semiconductor component with the second track. It reduces resistance and increases the current that can be passed from the semiconductor component to the second track.

In a further aspect of the invention, the second track comprises a protrusion. The protrusion can be V-shaped. A first side of the protrusion is located next to a side of the first semiconductor component and separated from said first semiconductor component by an insulating gap or an insulator. A second side of the protrusion is located next to a side of the second semiconductor component, and separated from said second semiconductor component by an insulating gap or an insulator.

The V-shaped protrusion can comprise a rounded tip. By tip of the V-shaped protrusion is understood an area where the first side and the second side of the protrusion intersect.

Alternatively, the protrusion can comprise a round shape, such as a circular segment.

In a further aspect of the invention, a gate signal conductor is disposed in the insulator gap between the protrusion and a semiconductor component.

Alternatively formulated, the gate signal conductor is disposed in the insulating gap between the protrusion and at least one of the first semiconductor component or the second semiconductor component.

By gate signal conductor is understood a conductor which connects to the gate connector of the first semiconductor component and/or the second semiconductor component. Thereby a gate signal is provided to the first semiconductor component and/or the second semiconductor component.

In a further aspect of the invention, at least the first semiconductor component and the second semiconductor component are oriented at an angle between 45 degrees and 135 degrees to each other. More preferable the angle is between 60 and 120 degrees, even more preferable the angle is between 80 and 100 degrees, most preferable the angle is 90 degrees.

The angle is measured between a side of the first semiconductor component facing the protrusion of a second track and the side of the second semiconductor component facing the protrusion of the second track.

Herewith is achieved a landing area located close to all involved semiconductor components ensuring the mean distance from the landing area to the semiconductors is (almost) identical. Equal distance leads to reduced inductance difference between the parallel loops.

Thereby the size of the loop can be reduced further. The difference in size of the loops is also reduced, reducing the difference in inductance between the loops.

In a further aspect of the invention, a landing area of the connecting means on the second track is no larger than 150%, preferably 120%, and most preferably 110% of the sum of the contact areas of the connecting means in contact with the second track.

Thus, the landing area is just large enough to cover the contact areas of the connecting means on the second track.

Reducing the landing area of the connecting means reduces the variation in impedances of the individual loops of the semiconductor power module, thereby increasing the performance of the semiconductor power module.

In a further aspect of the invention, the at least two or more semiconductor components are switching components.

In a further aspect of the invention, the connecting means comprises one or more wire bonds.

Alternatively, the connecting means can comprise one or more ribbon bonds.

As a further alternative, the connecting means can comprise one or more electrically conducting braids.

Any other electrically conduction component or a mixture of components known to the skilled person can be used.

In a further aspect of the invention, the two or more of the semiconductor components are based on wide-bandgap technologies.

In a further aspect of the invention, the two or more of the semiconductor components are based on silicon carbide (SIC) technologies.

In a further aspect of the invention, the two or more of the semiconductor components are based on gallium nitride (GaN).

In another embodiment of the invention, the first power contacts of each switching component are electrically connected to the first track by being mounted on the first track.

The term “mounted” is here used to mean the permanent connection of a device to a track, and may include an electrically conducting connection. Means of such connections include soldering, brazing and sintering.

A further aspect of the invention is the use of a semiconductor power module according to the description above in a vehicle. The vehicle can be a car.

A further aspect of the invention is the use of a semiconductor power module according to the description above in a vessel such as a waterborne vessel.

A further aspect of the invention is the use of a semiconductor power module according to the description above in an inverter.

A further aspect of the invention is the use of a semiconductor power module according to the description above in a stationary electronic apparatus. Stationary electronic apparatuses can be charging stations, energy storage devices such as battery storage systems, or infrastructure for utilisation of renewable energy.

### BRIEF DESCRIPTION OF THE DRAWINGS

The invention will become more fully understood from the detailed description given herein below. The accompanying drawings are given by way of illustration only, and thus, they are not limitative of the present invention. In the accompanying drawings:

FIGS. 1a and 1b show prior art layouts of a semiconductor power module,

FIG. 2 shows a representation of an embodiment of the inventive power module,

FIGS. 3a, 3b and 3c show representations of parts of an inventive power module from different viewing angles,

FIGS. 4a, 4b and 4c show parts of another power module according to the invention,

FIG. 5 shows the use of a power module according to the invention in a vehicle,

FIG. 6 shows the use of a power module according to the invention in a vessel,

FIG. 7 shows the use of a power module according to the invention in an inverter, and

FIG. 8 shows a part of a power module according to the invention comprising a gate signal conductor disposed in the insulator gap between a semiconductor component and the protrusion of the second track.

### DETAILED DESCRIPTION

In the following text the figures will be described on by one, and the different parts and positions seen in the figures will be numbered with the same numbers in the different figures. Not all parts and positions indicated in a specific figure will necessarily be discussed together with that figure.

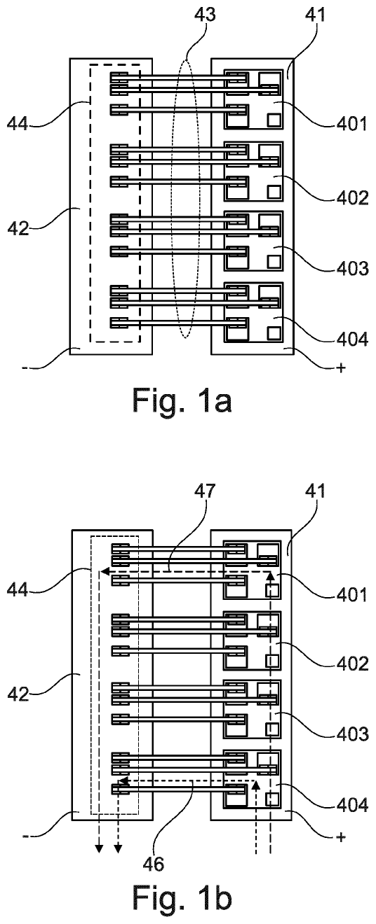

FIG. 1 shows an illustrative example of a prior art power module visualising the difference between the shortest commutation loop 46 and the longest commutation loop 47.

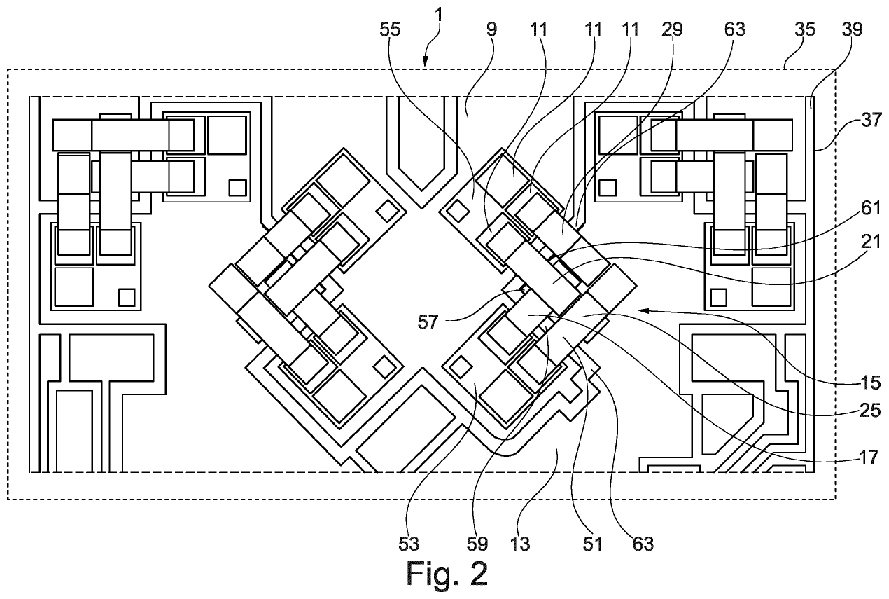

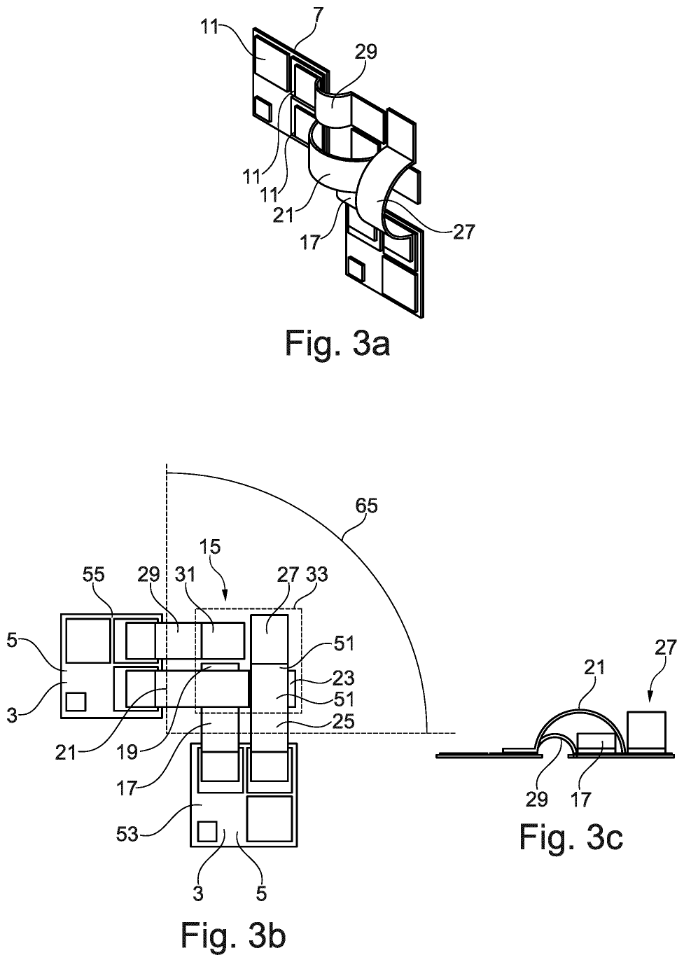

Referring now in detail to the drawings for the purpose of illustrating preferred embodiments of the present invention, an embodiment of the inventive power module 1 is shown in FIG. 2. Parts of the semiconductor power module 1 are shown in FIG. 3 from different viewing angles. FIG. 3a shows the parts of the power module in a perspective view. FIG. 3b shows a view from the top, and FIG. 3c shows a view from a side.

The power semiconductor module 1 comprises a range of semiconductor components 3 which are electrically connected in parallel. The semiconductor components are semiconductor switch components 5. The first power contacts 7 of each semiconductor component 3 are electrically connected to a first track 9. The second power contacts 11 of each semiconductor component 3 are electrically connected to a second track 13 by connecting means 15. The connecting means 15 comprises at least a first connecting element 17. The first connecting element 17 connects a first semiconductor component 53 of the two or more semiconductor components to the second track 13 via a first contact area 19.

A second connecting element 21 connects a second semiconductor component 55 of the two or more semiconductor components 53, 55 with the second track 13 by a second contact area 23. The second connecting element overlaps the first contact area 19. Alternatively, or additionally the second connecting element can overlap the first connecting element 17.

The semiconductor switching components are a wide-bandgap silicon carbide (SiC) component. Alternatively, Thyristors, JFETs, IGBTs and MOSFETs may be used, and they may be based on traditional silicon technology or wide-bandgap technologies such as silicon carbide (SiC) or gallium nitride (GaN).

The substrate 37 comprises an insulating base 39 with conducting tracks 9, 13 to form the circuitry required, attached to the insulating base 39. The substrate is a DBC (direct bonded copper) substrate formed of two conducting copper layers either side of an insulating ceramic layer. Other suitable substrates may include AMB (active metal braze) or other substrates well known in the field.

The connecting means 15 comprises ribbon bonds 51. Alternatively, the connecting means 51 may comprise wire bonds 43, electrically conducting tape, or an electrically conducting braid such as a woven or knitted braid with multiple strands, or any suitably shaped part of electrically conductive material.

Due to the second connecting element 25 at least partially overlapping the first contact area 19 and/or the first connecting element 21, the landing area 33 of the connecting elements 17, 21, 25, 29 can be significantly reduced in size. This reduces the difference in inductance between the individual current loops in the semiconductor power module.

The power semiconductor module comprises a third connecting element 25 connecting the first semiconductor component 53 with the second track 13 by a third contact area 27. The third connecting element 25 overlaps the second contact area 23 and partially overlaps the second connecting element 25.

The semiconductor power module comprises a fourth connecting element 29 connecting the second semiconductor component 55 with the second track via a fourth contact area.

The landing area 33 of the connecting elements can be further reduced in size, relative to a state of the art module where no overlap of the connecting elements is used. This further reduces the difference in inductance between the individual loops in the semiconductor power module.

The power semiconductor module comprises two connecting elements per semiconductor component. The connecting elements connect the semiconductor component to the second track.

A larger number of connecting elements improves the electrical connection of the semiconductor component with the second track. It reduces resistance and increases the ampacity of the semiconductor connection to the second track.

The second track 13 comprises a V-shaped protrusion 57. A first side 59 of the V-shaped protrusion 57 is located next to a side of the first semiconductor and separated from said first semiconductor by an insulating gap or an insulator 63. A second side of the V-shaped protrusion is located next to a side of the second semiconductor 55, and separated from said second semiconductor 55 by an insulating gap or an insulator 63.

The first semiconductor component and the second semiconductor component are oriented at an angle 65 of 90 degrees. Alternatively angles between 45 degrees and 135 degrees to each other.

Thereby the size of the loop can be reduced further. The difference in size of the loops is also reduced, reducing the difference in inductance between the loops.

The landing area 33 of the connecting means on the second track is no larger than 110% of the sum of the contact areas of the connecting means in contact with the second track. Alternatively, the landing area can be no larger than 150%, preferably 120% of the sum of the contact areas of the connecting means (17, 21, 25, 29) in contact with the second track.

Reducing the landing area of the connecting means reduces the variation in impedances of the individual semiconductor connections inside the power module, thereby increasing the performance of the semiconductor power module.

The at least two or more semiconductor components are switching components.

The connecting means 15 comprises four ribbon bonds 51.

Alternatively, the connecting means can comprise one or more wire bonds 43.

As a further alternative, the connecting means can comprise one or more electrically conducting braids. Any other electrically conducting components or a mixture of such components can be used.

The two or more of the semiconductor components are based on wide-bandgap technologies.

The two or more of the semiconductor components are based on silicon carbide (SIC) technologies.

The first power contacts of each switching component are electrically connected to the first track by being mounted on the first track.

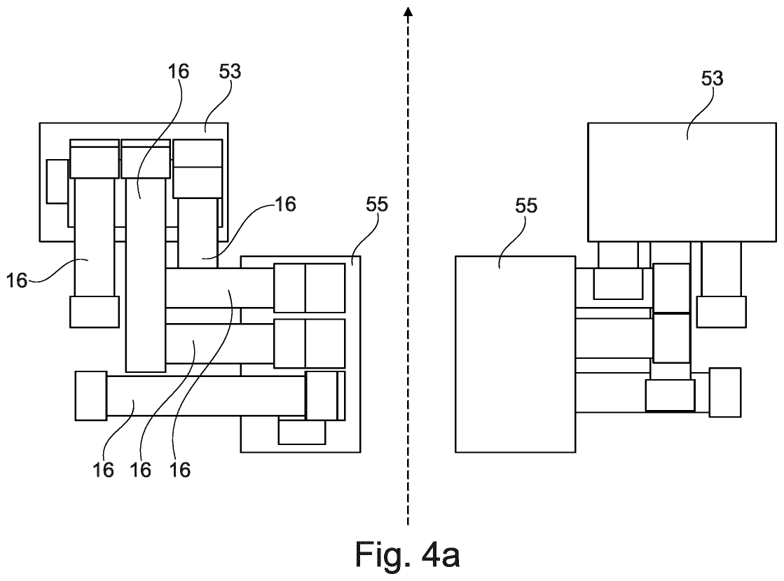

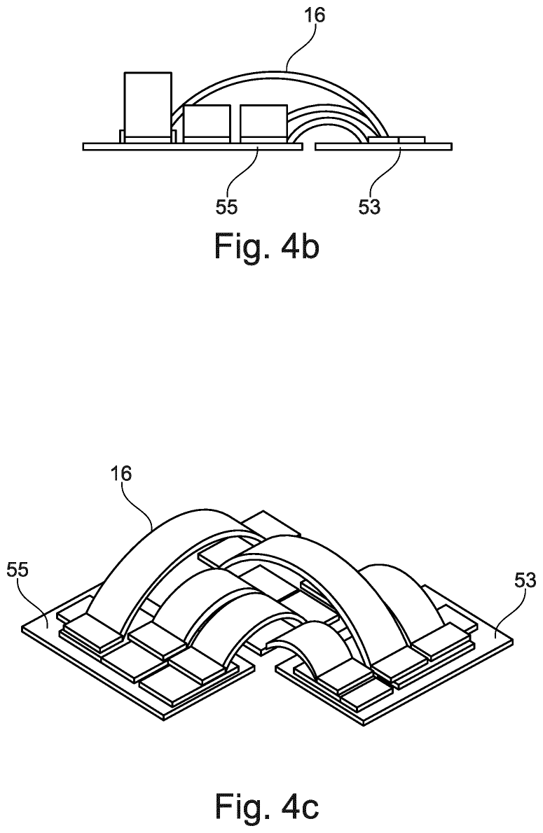

FIG. 4 shows parts of another embodiment of a power module according to the invention. FIG. 4a shows the parts from above (left) and from below (right) where the parts between left and right view have been rotated around the axis shown with a dashed line in the figure.

A first 53 and a second semiconductor component 55 are shown. Each semiconductor component is connected to the second track (not shown) with three connecting elements 16. The connecting elements overlap according to the invention. This scheme can be extended to any number of connections the area of the second power connectors and the landing area on the second track permits.

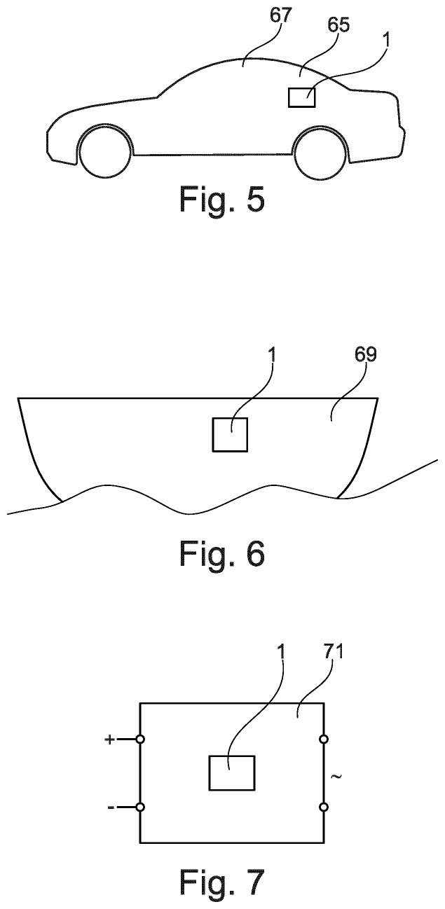

FIG. 5 shows the use of a power module according to the invention in a vehicles 65. The vehicle is a car 67. The car is a passenger car.

FIG. 6 shows the use of a power module 1 according to the invention in a vessel 69.

FIG. 7 shows the use of a power module 1 according to the invention in an inverter 71.

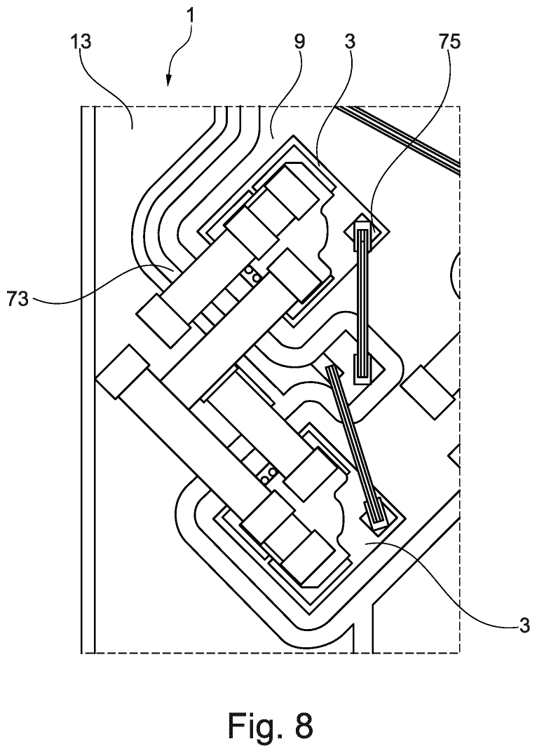

FIG. 8 shows a part of a power module 1 according to the invention, wherein a gate signal conductor 73 is disposed in the insulator gap 63 between the protrusion 57 and a semiconductor component 3.

Alternatively formulated, the gate signal conductor 73 is disposed in the insulating gap between the protrusion and at least one of the first semiconductor component or the second semiconductor component.

By gate signal conductor is understood a conductor which connects to the gate connector 75 of the first semiconductor component and/or the second semiconductor component. Thereby a gate signal is provided to the first semiconductor component and/or the second semiconductor component.

While the present disclosure has been illustrated and described with respect to a particular embodiment thereof, it should be appreciated by those of ordinary skill in the art that various modifications to this disclosure may be made without departing from the spirit and scope of the present disclosure.

What is claimed is:

1. A power semiconductor module comprising two or more semiconductor components which are electrically connected in parallel,
wherein each of the two or more semiconductor components comprises a first power contact and a second power contact,
wherein the first power contacts of each semiconductor component are electrically connected to a first track,
wherein the second power contacts of each semiconductor component are electrically connected to a second track by a connecting means,
and wherein the connecting means comprises at least a first connecting element connecting a first semiconductor component of the two or more semiconductor components to the second track via a first contact area,
and a second connecting element connecting a second semiconductor component of the two or more semiconductor components with the second track via a second contact area,
wherein the second connecting element partially overlaps the first contact area and/or first connecting element.

2. The power semiconductor module according to claim 1, comprising a third connecting element connecting the first semiconductor component with the second track by a third contact area,
wherein the third connecting element partially overlaps the first or second contact area and/or first or second connecting element.

3. The power semiconductor module according to claim 1, comprising at least two connecting elements per semiconductor component, which connecting elements connect the semiconductor component to the second track.

4. The power semiconductor module according to claim 1, wherein the second track comprises a protrusion, wherein a first side of the protrusion is located next to a side of the first semiconductor component and separated by said first semiconductor component by an insulating gap or an insulator, and wherein a second side of the protrusion is located next to a side of the second semiconductor component, and separated from said second semiconductor component by an insulating gap or an insulator.

5. The power semiconductor module according to claim 4, wherein the protrusion is V-shaped.

6. The power semiconductor module according to claim 4, wherein a gate signal conductor is disposed in the insulating gap between the protrusion and at least one of the first semiconductor component or the second semiconductor component.

7. The power semiconductor module according to claim 1, wherein at least the first semiconductor component and the second semiconductor component are oriented at an angle between 45 degrees and 135 degrees to each other.

8. The power semiconductor module according to claim 1, wherein a landing area of the connecting means on the second track is no larger than 150%, preferably 120%, and most preferably 110% of the sum of the contact areas of the connecting means in contact with the second track.

9. The power semiconductor module according to claim 1, wherein the at least two or more semiconductor components are switching components.

10. The power semiconductor module according to claim 1, wherein the connecting means comprises one or more ribbon bonds.

11. Use of a power module according to claim 1 in a vehicle.

12. Use of a power module according to claim 1 in an inverter.

13. The power semiconductor module according to claim 2, comprising at least two connecting elements per semiconductor component, which connecting elements connect the semiconductor component to the second track.

14. The power semiconductor module according to claim 2, wherein the second track comprises a protrusion, wherein a first side of the protrusion is located next to a side of the first semiconductor component and separated by said first semiconductor component by an insulating gap or an insulator, and wherein a second side of the protrusion is located next to a side of the second semiconductor component, and separated from said second semiconductor component by an insulating gap or an insulator.

15. The power semiconductor module according to claim 3, wherein the second track comprises a protrusion, wherein a first side of the protrusion is located next to a side of the first semiconductor component and separated by said first semiconductor component by an insulating gap or an insulator, and wherein a second side of the protrusion is located next to a side of the second semiconductor component, and separated from said second semiconductor component by an insulating gap or an insulator.

16. The power semiconductor module according to claim 2, wherein at least the first semiconductor component and the second semiconductor component are oriented at an angle between 45 degrees and 135 degrees to each other.

17. The power semiconductor module according to claim 3, wherein at least the first semiconductor component and the second semiconductor component are oriented at an angle between 45 degrees and 135 degrees to each other.

18. The power semiconductor module according to claim 4, wherein at least the first semiconductor component and the second semiconductor component are oriented at an angle between 45 degrees and 135 degrees to each other.

19. The power semiconductor module according to claim 5, wherein at least the first semiconductor component and the second semiconductor component are oriented at an angle between 45 degrees and 135 degrees to each other.

20. The power semiconductor module according to claim 6, wherein at least the first semiconductor component and the second semiconductor component are oriented at an angle between 45 degrees and 135 degrees to each other.
